(19) United States
(12) Patent Application Publication
(10) Pub. No.: US 2020/0169704 A1
(43) Pub. Date: May 28, 2020

(54) IMAGE PICKUP ELEMENT AND IMAGE PICKUP APPARATUS

(71) Applicant: Sony Corporation, Tokyo (JP)

(72) Inventor: Shinichi Fujii, Kanagawa (JP)

(21) Appl. No.: 16/638,243

(22) PCT Filed: Aug. 3, 2018
(86) PCT No.: PCT/JP2018/029181

§ 371 Date: Feb. 11, 2020

(30) Foreign Application Priority Data
Aug. 18, 2017 (JP) 2017-158066

(51) Int. Cl. H04N 9/077; G03B 13/36; H01L 27/146; H04N 5/374; G02B 7/34

(52) U.S. Cl. CPC H04N 9/077; G03B 13/36; H01L 27/14603; H01L 27/14643; H04N 5/374; G02B 7/34; H01L 27/14609

(57) ABSTRACT

The present disclosure relates to an image pickup element and an image pickup apparatus capable of achieving an improvement in focus accuracy using focal plane phase detection.

An image pickup element includes: an ordinary pixel that converts an electric charge generated by photoelectric conversion into a voltage with first conversion efficiency and that outputs a pixel signal used to construct an image; and a phase difference detection pixel that converts an electric charge generated by the photoelectric conversion into a voltage with second conversion efficiency higher than the first conversion efficiency and that outputs a pixel signal used for phase difference detection. Light is blocked on the phase difference pixel by approximately a half of a light-receiving area by a phase difference light blocking film that exhibits a light blocking effect, and the second conversion efficiency is approximately twice as high as the first conversion efficiency of the first pixel. The present technology is applicable to, for example, a CMOS image sensor.

### TECHNICAL FIELD

The present disclosure relates to an image pickup element and an image pickup apparatus, and particularly relates to an image pickup element and an image pickup apparatus capable of achieving an improvement in focus accuracy using focal plane phase detection.

### BACKGROUND ART

A conventional electronic apparatus having an image pickup function such as a digital still camera and a digital video camera employs a solid-state image pickup element, which is, for example, a CCD (Charge Coupled Device) image sensor or a CMOS (Complementary Metal Oxide Semiconductor) image sensor. The solid-state image pickup element has pixels each of which has a combination of a PD (photodiode) performing photoelectric conversion and a plurality of transistors, and constructs an image on the basis of pixel signals output from a plurality of pixels placed on an image surface on which a subject image is formed.

Furthermore, a recent image pickup apparatus has a function to perform autofocus using focal plane phase detection by providing phase difference pixels for detecting a phase difference on the image surface of the solid-state image pickup element. The autofocus using such focal plane phase detection can measure a distance without driving a focus lens and, therefore, focus on a subject at a higher speed than that of autofocus using a contrast.

PTL 1, for example, discloses a solid-state image pickup apparatus capable of achieving improvements in speed and accuracy of autofocus by providing a structure that can simultaneously perform exposure of two PDs and reading signals therefrom.

### CITATION LIST

### Patent Literature

### [PTL 1]

Japanese Patent Laid-Open No. 2015-91025

### SUMMARY

### Technical Problem

Incidentally, a solid-state image pickup element having high-sensitivity characteristics tends to grow in pixel size for receiving more light. This size growth involves increasing a distance between the phase difference pixels, which possibly causes autofocus accuracy degradation.

The present disclosure has been achieved in the light of such circumstances, and an object of the present disclosure is to make it possible to achieve an improvement in focus accuracy using focal plane phase detection.

### Solution to Problem

An image pickup element according to one aspect of the present disclosure includes: a first pixel that converts an electric charge generated by photoelectric conversion into a voltage with first conversion efficiency and that outputs a pixel signal used to construct an image; and a second pixel that converts an electric charge generated by the photoelectric conversion into a voltage with second conversion efficiency higher than the first conversion efficiency and that outputs a pixel signal used for phase difference detection.

An image pickup apparatus according to one aspect of the present disclosure includes an image pickup element including: a first pixel that converts an electric charge generated by photoelectric conversion into a voltage with first conversion efficiency and that outputs a pixel signal used to construct an image; and a second pixel that converts an electric charge generated by the photoelectric conversion into a voltage with second conversion efficiency higher than the first conversion efficiency and that outputs a pixel signal used for phase difference detection.

According to one aspect of the present disclosure, an electric charge generated by a photoelectric conversion is converted into a voltage with first conversion efficiency by a first pixel and the voltage is used to construct an image, and an electric charge generated by the photoelectric conversion is converted into a voltage with second conversion efficiency higher than the first conversion efficiency by a second pixel and the voltage is used for phase difference detection.

### Advantageous Effect of Invention

According to one aspect of the present disclosure, it is possible to achieve an improvement in focus accuracy using focal plane phase detection.

It is noted that advantages are not always limited to those described herein but may be any of the advantages described in the present disclosure.

### BRIEF DESCRIPTION OF DRAWINGS

FIG. 1 is a block diagram depicting an example of a configuration of an embodiment of an image pickup element to which the present technology is applied.

FIG. 2 is a diagram depicting a first placement pattern of ordinary pixels and phase difference pixels.

FIG. 3 are diagrams depicting first to third examples of a configuration of the phase difference pixel.

FIG. 4 is an explanatory diagram of conversion efficiency of the phase difference pixel.

FIG. 5 is a diagram depicting a second placement pattern of ordinary pixels and phase difference pixels.

FIG. 6 are diagrams depicting fourth and fifth examples of the configuration of the phase difference pixel.

FIG. 7 are explanatory diagrams of merits of a configuration of adopting a large-sized microlens.

FIG. 8 are diagrams depicting an example of an interconnection configuration in a structure of performing four-pixel addition.

FIG. 9 are explanatory diagrams of examples of a configuration of the phase difference pixel that can be switched over between an ordinary pixel mode and a phase difference pixel mode.

FIG. 10 is a block diagram depicting an example of a configuration of an image pickup apparatus.

FIG. 11 is a diagram depicting usage examples of using an image sensor.

FIG. 12 is a view schematically depicting a general configuration of a surgery room system.

FIG. 13 is a view depicting an example of display of an operation screen image of a centralized operation panel.

FIG. 14 is a view illustrating an example of a state of surgery to which the surgery room system is applied.

FIG. 15 is a block diagram depicting an example of a functional configuration of a camera head and a camera control unit (CCU) depicted in FIG. 14.

### DESCRIPTION OF EMBODIMENTS

Specific embodiments to which the present technology is applied will be described in detail hereinafter with reference to the drawings.

### <Example of Configuration of Imaging Element>

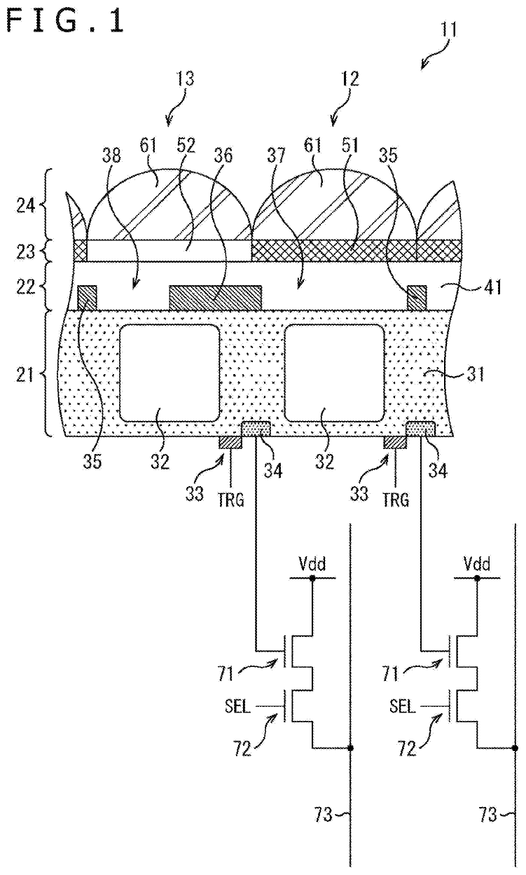

FIG. 1 is a diagram depicting an example of a configuration of an embodiment of an image pickup element to which the present technology is applied.

An image pickup element 11 is configured such that a plurality of pixels is placed in an array, and it is assumed that out of those pixels, ordinary pixels outputting pixel signals used to construct an image are ordinary pixels 12 and pixels outputting pixel signals used for focal plane phase detection are phase difference pixels 13.

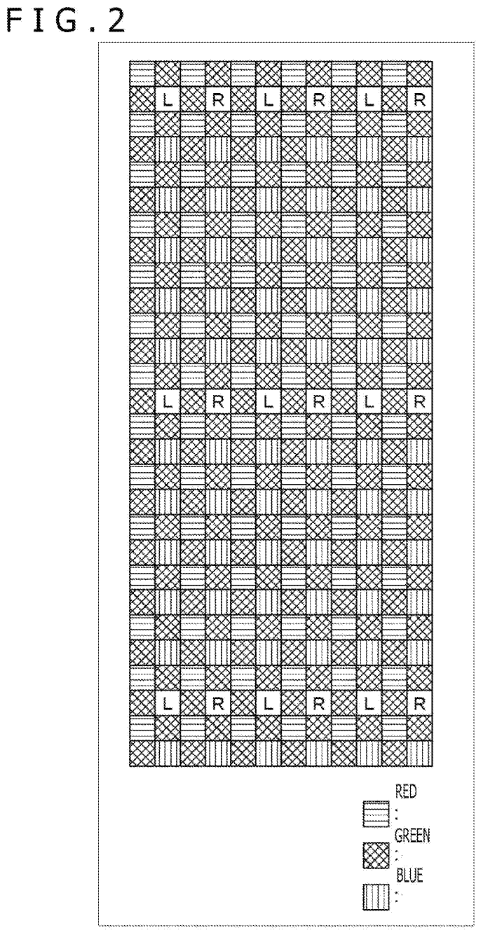

The image pickup element 11 as depicted in FIG. 2 is a back irradiation image pickup element in which a rear surface (surface turning up in FIG. 1) of a semiconductor substrate 21 is irradiated with light, and the image pickup element 11 is configured such that a planarization layer 22, a filter layer 23, and an on-chip lens layer 24 are stacked on the rear surface of the semiconductor substrate 21. In addition, an interconnection layer is stacked on a front surface of the semiconductor substrate 21 although not depicted.

The semiconductor substrate 21 is configured by, for example, a silicon wafer 31 obtained by slicing a monocrystalline silicon thin, and is provided with a PD 32 that accumulates an electric charge generated by performing photoelectric conversion and that is provided per ordinary pixel 12 or per phase difference pixel 13. Furthermore, a transfer transistor 33 that transfers the electric charge accumulated in the PD 32, and an FD (Floating Diffusion) section 34 that is a floating diffusion region temporarily accumulating the electric charge transferred via the transfer transistor 33 and having a predetermined capacity are formed on the front surface of the semiconductor substrate 21.

Moreover, an inter-pixel light blocking film 35 that blocks light between the ordinary pixels 12 or between the ordinary pixel 12 and the phase difference pixel 13 and a phase difference light blocking film 36 that blocks light on the phase difference pixel 13 by a half of a light-receiving area thereof are formed on the rear surface of the semiconductor substrate 21. By forming the inter-pixel light blocking film 35 and the phase difference light blocking film 36 each exhibiting a light blocking effect as described above, an opening portion 37 through which the light passes by an entire light-receiving area is formed in the ordinary pixel 12, and an opening portion 38 through which the light passes by a half of the light-receiving area is formed in the phase difference pixel 13.

The planarization layer 22 is configured by, for example, an oxide film 41 exhibiting an insulating property for insulating the rear surface of the semiconductor substrate 21, and the oxide film 41 planarizes irregularities on the rear surface of the semiconductor substrate 21.

The filter layer 23 is configured such that a color filter 51 that transmits light of a predetermined color (for example, red, green, or blue, as depicted in FIG. 2) is placed per ordinary pixel 12 and that a transparent filter 52 is placed to correspond to each phase difference pixel 13.

The on-chip lens layer 24 is configured by a microlens 61 placed per ordinary pixel 12 and a microlens 61 placed per phase difference pixel 13, and each microlens 61 collects light. Furthermore, the phase difference light blocking film 36 provided in the phase difference pixel 13 is formed to block light at a position of a pupil of the microlens 61 on the phase difference pixel 13 by a half of the light-receiving area thereof.

Moreover, in the image pickup element 11, a gate electrode of an amplification transistor 71 is connected to the FD section 34 of each of the ordinary pixel 12 and the phase difference pixel 13, and the amplification transistor 71 is connected to a vertical signal line 73 via a selection transistor 72 driven in accordance with a selection signal SEL. In the image pickup element 11, the electric charge is transferred from the PD 32 to the FD section 34 in accordance with, for example, a transfer signal TRG supplied to a gate electrode of the transfer transistor 33, and a potential in response to a level of the electric charge is applied to the gate electrode of the amplification transistor 71. The amplification transistor 71 together with a constant current source, which is not depicted, configures a source follower, converts the electrical charge accumulated in the FD section 34 into a pixel signal, and outputs the pixel signal to an AD (Analog to Digital) converter via the vertical signal line 73. In other words, with the configuration of connecting the FD section 34 to the gate electrode of the amplification transistor 71, the amplification transistor 71 functions as an electric charge/voltage conversion section that converts the electric charge generated in the PD 32 into a voltage representing the pixel signal output from the vertical signal line 73 with predetermined conversion efficiency in response to, for example, the capacity of the FD section 34.

The image pickup element 11 configured with the ordinary pixels 12 and the phase difference pixels 13 described above can focus on a subject at a high speed by, for example, driving a focus lens on the basis of a phase difference signal output from each phase difference pixel 13. On the other hand, portions where the phase difference pixels 13 are placed are handled as defective pixels at a time of constructing an image; thus, the phase difference pixels 13 are normally, discretely placed in the image pickup element 11 to suppress image quality degradation.

### <First Placement Pattern>

FIG. 2 depicts an example of a first placement pattern of the ordinary pixels 12 and the phase difference pixels 13.

As depicted in FIG. 2, red, green, and blue color filters 51 are placed in the ordinary pixels 12 in accordance with a so-called Bayer array. In addition, the phase difference pixels 13 are placed to replace the blue ordinary pixels 12 at intervals of a predetermined number of lines.

On a line on which the phase difference pixels 13 are placed, placement locations L and R are provided to put one ordinary pixel 12 between the phase difference pixels 13. For example, the phase difference pixel 13 having the opening portion 38 provided on a left side is placed in the placement location L, and the phase difference pixel 13 having the opening portion 38 provided on a right side is placed in the placement location R. In other words, in the placement pattern depicted in FIG. 2, the phase difference pixel 13 having the opening portion 38 provided on the left side and the phase difference pixel 13 having the opening portion 38 provided on the right side are alternately placed in a row direction.

It is noted that the placement pattern of the ordinary pixels 12 and the phase difference pixels 13 depicted in FIG. 2 is given as an example and that the ordinary pixels 12 and the phase difference pixels 13 may be placed in a placement pattern other than this placement pattern.

### <Examples of Configuration of Phase Difference Pixel>

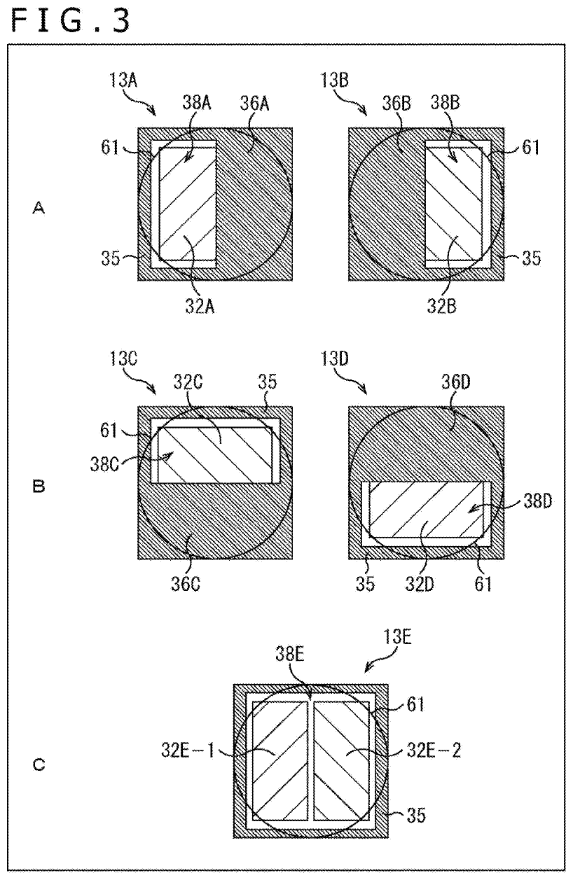

A planar configuration of the phase difference pixel 13 will be described with reference to FIGS. 3. FIG. 3A depicts a first example of the configuration of the phase difference pixel 13, FIG. 3B depicts a second example of the configuration of the phase difference pixel 13, and FIG. 3C depicts a third example of the configuration of the phase difference pixel 13.

As depicted in FIG. 3A, light is blocked by a phase difference light blocking film 36A on a right half of a phase difference pixel 13A, light passing through an opening portion 38A provided on the left side is received by a PD 32A, and the phase difference pixel 13A outputs a pixel signal in response to a quantity of the light. Likewise, light is blocked by a phase difference light blocking film 36B on a left half of a phase difference pixel 13B, light passing through an opening portion 38B provided on the right side is received by a PD 32B, and the phase difference pixel 13B outputs a pixel signal in response to a quantity of the light.

The image pickup element 11 provided with such phase difference pixels 13A and 13B detects a phase difference on the basis of a lateral deviation between an image constructed from the pixel signals output from the phase difference pixels 13A and an image constructed from the pixel signals output from the phase difference pixels 13B.

Furthermore, as depicted in FIG. 3B, light is blocked by a phase difference light blocking film 36C on a lower half of a phase difference pixel 13C, light passing through an opening portion 38C provided on an upper side is received by a PD 32C, and the phase difference pixel 13C outputs a pixel signal in response to a quantity of the light. Likewise, light is blocked by a phase difference light blocking film 36D on an upper half of a phase difference pixel 13D, light passing through an opening portion 38D provided on a lower side is received by a PD 32D, and the phase difference pixel 13D outputs a pixel signal in response to a quantity of the light.

The image pickup element 11 provided with such phase difference pixels 13C and 13D detects a phase difference on the basis of a vertical deviation between an image constructed from the pixel signals output from the phase difference pixel 13C and an image constructed from the pixel signals output from the phase difference pixel 13D.

Moreover, as depicted in FIG. 3C, a phase difference pixel 13E does not block light by the phase difference light blocking film 36 described above, and is configured with two horizontally split PDs 32E-1 and 32E-2. Therefore, light radiated onto the left side of a light-receiving surface of the phase difference pixel 13E is received by the PD 32E-1 and the phase difference pixel 13E outputs a pixel signal in response to a quantity of the light, while light radiated onto the right side of the light-receiving surface thereof is received by the PD 32E-2 and the phase difference pixel 13E outputs a pixel signal in response to a quantity of the light.

The image pickup element 11 provided with such phase difference pixels 13E detects a phase difference on the basis of a lateral deviation between an image constructed from the pixel signals output from the PDs 32E-1 and an image constructed from the pixel signals output from the PDs 32E-2.

It is noted that the image pickup element 11 may detect a phase difference using phase difference pixels provided not with the two horizontally split PDs as in the phase difference pixel 13E but with two vertically split PDs.

In this way, the phase difference pixel 13 is configured such that the area by which the PD 32 receives the light is a half of the entire area or such that the PD 32 itself is split into halves. Owing to this, the electric charge generated by photoelectric conversion in the phase difference pixel 13 is normally half as large as the electric charge generated in the ordinary pixel 12, an output level of the pixel signal of the phase difference pixel 13 is half as high as that of the ordinary pixel 12. Therefore, it is estimated that accuracy degradation at a time of autofocus occurs as a result of, for example, a relative increase in quantization error at a time of performing AD conversion on the pixel signal.

To address the problem, the image pickup element 11 is configured such that conversion efficiency (ratio of the voltage of the pixel signal output from the vertical signal line 73 to one electric charge generated in the PD 32) of the phase difference pixel 13 at the time of converting the electric charge generated by the photoelectric conversion in the phase difference pixel 13 into the pixel signal is set twice as high as conversion efficiency of the ordinary pixel 12. The image pickup element 11 can thereby make the output level of the pixel signal equivalent to that of the pixel signal of the ordinary pixel 12 even if the electric charge generated by the photoelectric conversion is half as large as that of the ordinary pixel 12. It is, therefore, possible to suppress an adverse influence of the quantization error described above and avoid a reduction in autofocus accuracy.

For example, as described with reference to FIG. 1, the electric charge generated in the PD 32 is transferred to the FD section 34 and converted into the pixel signal in the amplification transistor 71, and the conversion efficiency for converting the electric charge into the pixel signal is in response to the capacity of the FD section 34. In other words, the voltage V (=C×Q) of the pixel signal is determined on the basis of an electric charge Q and a capacity C of the FD section 34.

Therefore, designing the image pickup element 11 in such a manner that the capacity of the FD section 34 of each phase difference pixel 13 is set, for example, to be half as large as that of the FD section 34 of each ordinary pixel 12 during manufacturing enables the conversion efficiency of the phase difference pixel 13 to be set twice as high as that of the ordinary pixel 12. Alternatively, connecting a capacitor that can, for example, double the capacity of the FD section 34 of each ordinary pixel 12 enables the conversion efficiency of each phase difference pixel 13 to be relatively set twice as high as that of the ordinary pixel 12. In this way, the conversion efficiency of the phase difference pixel 13 is set twice as high as that of the ordinary pixel 12 in accordance with a proportion of the light-receiving area of the PD 32 of the phase difference pixel 13 to the light-receiving area of the PD 32 of the ordinary pixel 12. It is noted that setting of the conversion efficiency is not limited to this setting. If the conversion efficiency of the phase difference pixel 13 is set at least higher than that of the ordinary pixel 12, it is possible to increase the output level of the phase difference pixel 13 and suppress the adverse influence of the quantization error.

### <Conversion Efficiency of Phase Difference Pixel>

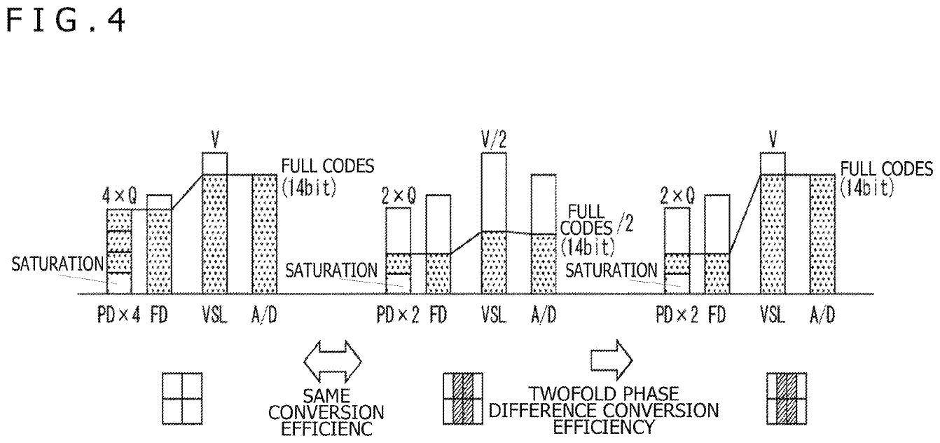

The conversion efficiency of the phase difference pixel 13 will be described with reference to FIG. 4.

FIG. 4 represents, for example, that in a case in which one FD section 34 performs pixel addition for adding up electric charges obtained by the photoelectric conversion in the four PDs 32, the amplification transistor 71 converts the electric charges into pixel signals and outputs the pixel signals to the vertical signal line (VSL) 73.

As depicted on a left side of FIG. 4, the conversion efficiency of the ordinary pixel 12 is (μV/e⁻) with which while a saturated quantity of the electric charge of each PD 32 is assumed as Q, a saturated quantity of electric charges (4×Q) obtained by adding up the electric charges generated in the four PDs 32 is converted into the voltage (V) of the pixel signals that is, for example, to be output to a 14-bit AD converter with full codes.

On the other hand, as depicted at a center of FIG. 4, if the phase difference pixel 13 converts a saturated quantity of electric charges (2×Q) obtained by adding up electric charges generated in the two PDs 32 into a voltage (V/2) of pixel signals that is to be output to the 14-bit AD converter with approximately a half of the full codes. Since the output level is low at a time of image pickup particularly in a low illuminance environment, the influence of the quantization error relatively increases, resulting in autofocus accuracy degradation.

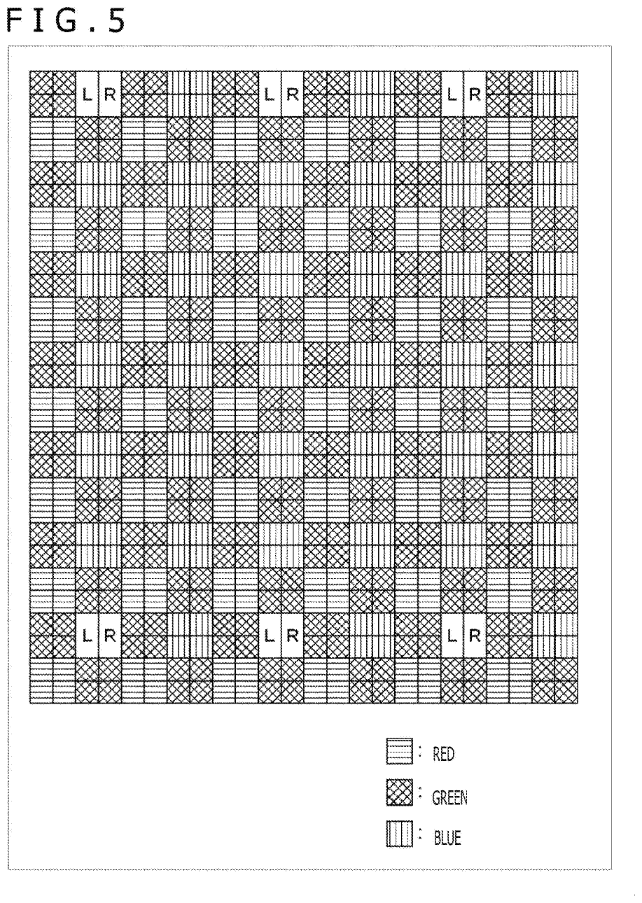

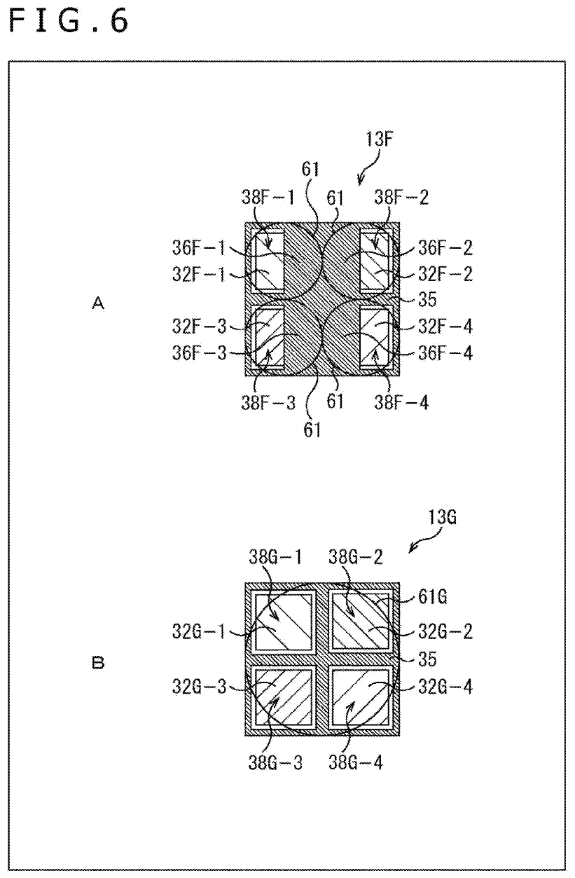

To address the problem, as depicted on a right side of FIG. 4, setting the conversion efficiency of the phase difference pixel 13 twice as high as that of the ordinary pixel 12 at the time of converting the electric charge into the pixel signal makes it possible to convert the saturated quantity of electric charges (2×Q) obtained by adding up the electric charges generated in the two PDs 32 into the voltage (V) of the pixel signals that is to be output to the 14-bit AD converter with the full codes. It is thereby possible to ensure a sufficient output level and mitigate the influence of the quantization error even in the case of the image pickup particularly in the low illuminance environment. In other words, setting the conversion efficiency in accordance with the proportion of the light-receiving area of the ordinary pixel 12 to the light-receiving area of the phase difference pixel 13 (that is, setting the conversion efficiency of the phase difference pixel 13 twice as high as that of the ordinary pixel 12 in a case in which the light-receiving area of the phase difference pixel 13 is half as large as that of the ordinary pixel 12) makes it possible to set the output level of the pixel signal of the phase difference pixel 13 to an appropriate output level similarly to that of the pixel signal of the ordinary pixel 12. Applying such a configuration to, for example, a 2×2 Bayer array to be described later with reference to FIGS. 5 and 6 enables realization of more accurate autofocus.

### <Second Placement Pattern>

FIG. 5 depicts an example of a second placement pattern of the ordinary pixels 12 and the phase difference pixels 13.

As depicted in FIG. 5, four ordinary pixels 12 are configured, as 2×2 in length and width, to receive the same color, and the red, green, or blue color filter 51 is placed per these four pixels in accordance with the so-called Bayer array. In addition, the phase difference pixels 13 are placed to replace regions of 2×2 ordinary pixels 12 in length and width, that is, four blue ordinary pixels 12 at intervals of a predetermined number of lines.

In the placement pattern depicted in FIG. 5, placement locations L and R each at a magnitude of two pixels in a column direction are placed adjacently in the row direction. In addition, the PDs 32 that receive light radiated onto the left side are placed in the placement location L and the PDs 32 that receive light radiated onto the right side are placed in the placement location R, and the phase difference pixel 13 is configured with the four PDs 32. In other words, out of the four PDs 32 as 2×2 PDs, the two PDs 32 each having the opening portion 38 provided on the left side are placed in the left placement location L to be aligned in the column direction, and the two PDs 32 each having the opening portion 38 provided on the right side are placed in the right placement location R to be aligned in the column direction. The phase difference pixels 13 each configured with these four PDs 32 are placed in the row direction with an interval corresponding to the three phase difference pixels 13 given between the phase difference pixels 13.

The placement of the color filters in units of four pixels in the Bayer array as described above will be referred to as “2×2 Bayer array” hereinafter, as appropriate.

In related art, it is estimated that the following problem occurs to a solid-state image pickup element having high-sensitivity characteristics. As a pixel size grows for receiving more light, a distance between the phase difference pixels is increased and a degree of matching of waveforms of the pixel signals output from those phase difference pixels is reduced. In the 2×2 Bayer array depicted in FIG. 5, by contrast, the placement locations L and R are provided adjacently and the distance between the phase difference pixels can be, therefore, reduced; thus, it is possible to realize highly accurate autofocus without a reduction in the degree of matching of waveforms of the pixel signals described above.

### <Examples of Configuration of Phase Difference Pixel>

A planar configuration of the phase difference pixel 13 used in the 2×2 Bayer array depicted in FIG. 5 will be described with reference to FIGS. 6. FIG. 6A depicts a fourth example of the configuration of the phase difference pixel 13, and FIG. 6B depicts a fifth example of the configuration of the phase difference pixel 13.

As depicted in FIG. 6A, a phase difference pixel 13F is configured with a PD 32F-1 having an opening portion 38F-1 provided on a left side, a PD 32F-2 having an opening portion 38F-2 provided on a right side, a PD 32F-3 having an opening portion 38F-3 provided on a left side, and a PD 32F-4 having an opening portion 38F-4 provided on a right side. In addition, the microlenses 61 at the same magnitude as that of the microlens 61 of the ordinary pixel 12 are provided to correspond to the PDs 32F-1 to 32F-4, respectively in the phase difference pixel 13F.

As depicted in FIG. 6B, a phase difference pixel 13G is configured with four PDs 32G-1 to 32G-4 as 4×4 PDs in length and width, and opening portions 38G-1 to 38G-4 at the same magnitude as that of the opening portion 38 of the ordinary pixel 12 are formed to correspond to the PDs 32G-1 to 32G-4, respectively. In addition, the phase difference pixel 13G is provided with a large-sized microlens 61G at a size according to a region where these four PDs 32G-1 to 32G-4 are placed.

It is noted herein that in the case of, for example, the phase difference pixels 13A and 13B of FIG. 3A, the phase difference light blocking films 36A and 36B block the light each by the half of the light-receiving area and a sensitivity of each of the phase difference pixels 13A and 13B is reduced to be approximately half as high as that of the pixel without light blocking. The phase difference pixel 13G, by contrast, is configured without the phase difference light blocking film 36; thus, it is possible to avoid a reduction in sensitivity due to light blocking. In other words, the sensitivity of the phase difference pixel 13G is approximately twice as high as that of the phase difference pixels 13A and 13B of FIG. 3A, and can obtain more favorable autofocus accuracy even in the case of the image pickup in, for example, the low illuminance environment.

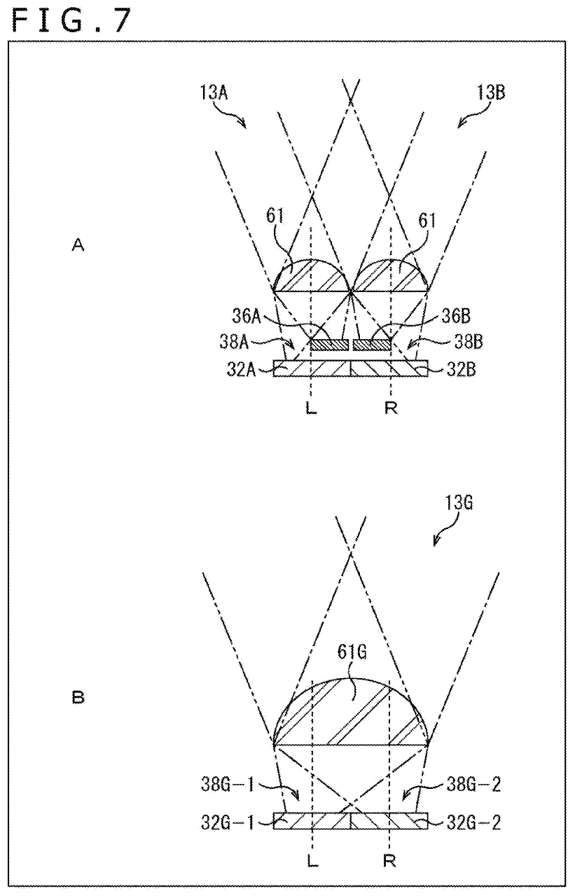

Merits of the configuration of adopting the large-sized microlens 61G as in the case of the phase difference pixel 13G of FIG. 6B will now be described with reference to FIGS. 7.

FIG. 7A schematically depicts rays of light incident on the phase difference pixels 13A and 13B in a configuration of, for example, placement of the microlens 61 per PD 32 as in the case of the phase difference pixels 13A and 13B of FIG. 3A. FIG. 7B schematically depicts rays of light incident on the phase difference pixel 13G in a configuration of placement of the microlens 61G at the magnitude corresponding to the region of the four pixels as in the case of the phase difference pixel 13G of FIG. 6B. Furthermore, in FIGS. 7A and 7B, the light incident from the right side is denoted by a dot-and-dash line and the light incident from the right side is denoted by a chain double-dashed line.

As depicted in FIG. 7A, the phase difference pixel 13A is configured such that the phase difference light blocking film 36A blocks the light on the right half by the half of the light-receiving area and the light radiated from the right side and passing through the opening portion 38A is received by the PD 32A. Likewise, the phase difference pixel 13B is configured such that the phase difference light blocking film 36B blocks the light on the left half by the half of the light-receiving area and the light radiated from the left side and passing through the opening portion 38B is received by the PD 32B. Therefore, each of the phase difference pixels 13A and 13B can receive only a half of the radiated light.

On the other hand, as depicted in FIG. 7B, the phase difference pixel 13G is configured with the large-sized microlens 61G, the light radiated from the right side and passing through the opening portion 38G-1 is received by the PD 32G-1, and the light radiated from the left side and passing through the opening portion 38G-2 is received by the PD 32G-2. Therefore, because of the configuration of not blocking the radiated light, the phase difference pixel 13G can avoid a light quantity loss and can receive the light at a light quantity twice as large as those of the phase difference pixels 13A and 13B.

Owing to this, the sensitivity of the phase difference pixel 13G can be improved as the phase difference pixel 13G can receive more light, and can obtain more favorable focus accuracy even in the case of the image pickup in the low illuminance environment. It is noted that the phase difference pixels 13G, 13A, and 13B are generally equivalent in phase difference and separation characteristics.

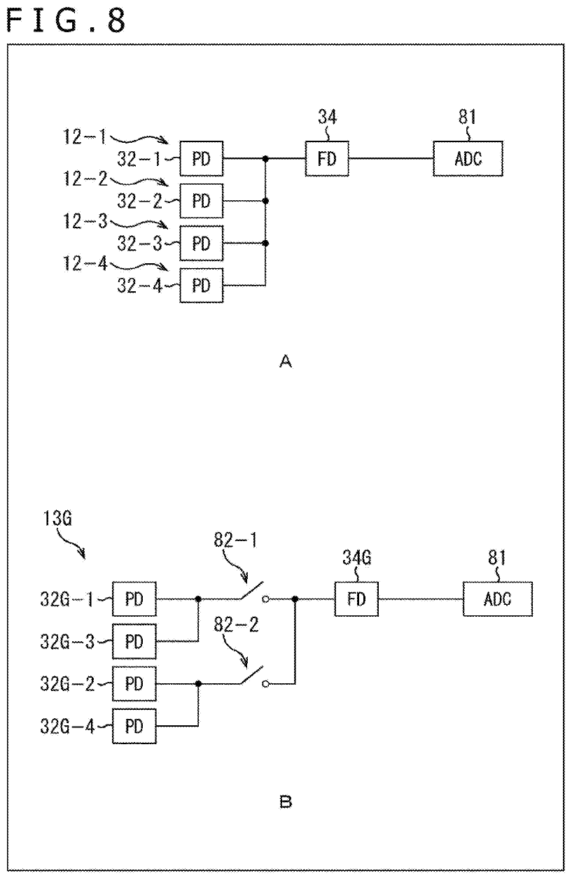

An interconnection configuration of the phase difference pixel 13G will now be described with reference to FIG. 8.

FIG. 8A depicts an example of an interconnection configuration of ordinary pixels 12 subjected to four-pixel addition, while FIG. 8B depicts an example of an interconnection configuration of the phase difference pixel 13G.

As depicted in FIG. 8A, PDs 32-1 to 32-4 provided in four ordinary pixels 12-1 to 12-4 are connected to one FD section 34, and the FD section 34 is connected to an AD converter 81 via the amplification transistor 71 depicted in FIG. 1.

As depicted in FIG. 8B, in the phase difference pixel 13G, the PDs 32G-1 and 32G-3 placed in the placement location L are connected to an FD section 34G via a switching transistor 82-1, and the PDs 32G-2 and 32G-4 placed in the placement location R are connected to the FD section 34G via a switching transistor 82-2. In addition, electric charges generated in the PDs 32G-1 and 32G-3 are supplied to the FD section 34G at timing different from timing of supplying thereto electric charges generated in the PDs 32G-2 and 32G-4 by the switching transistors 82-1 and 82-2.

At this time, in a case where an input voltage to the AD converter 81 is common to the ordinary pixels 12 and the phase difference pixel 13G, it is necessary to design the image pickup element 11 in such a manner that the capacity of the FD section 34G of the phase difference pixel 13G is half as large as those of the FD sections 34G of the ordinary pixels 12-1 to 12-4 for setting the conversion efficiency of the phase difference pixel 13G twice as high as that of the ordinary pixels 12 as described above.

It is noted that the placement pattern of the phase difference pixels 13 is not limited to the examples depicted in FIGS. 2 and 5 in the image pickup element 11. A placement pattern, for example, in which a pair of the phase difference pixels 13A and 13B and a pair of the phase difference pixels 13C and 13D are provided in a mixed manner and the pairs are alternately placed at intervals of a predetermined number of lines may be adopted. Furthermore, a placement pattern, for example, in which lines on which the phase difference pixels 13A are placed differ from those on which the phase difference pixels 13B are placed may be adopted. Moreover, the configuration of the phase difference pixel 13 is not limited to the various examples of the configuration described above and a configuration of, for example, blocking light along diagonal lines may be adopted as the configuration of the phase difference pixel 13.

<Structure of Switchover between Ordinary Pixel Mode and Phase Difference Pixel Mode>

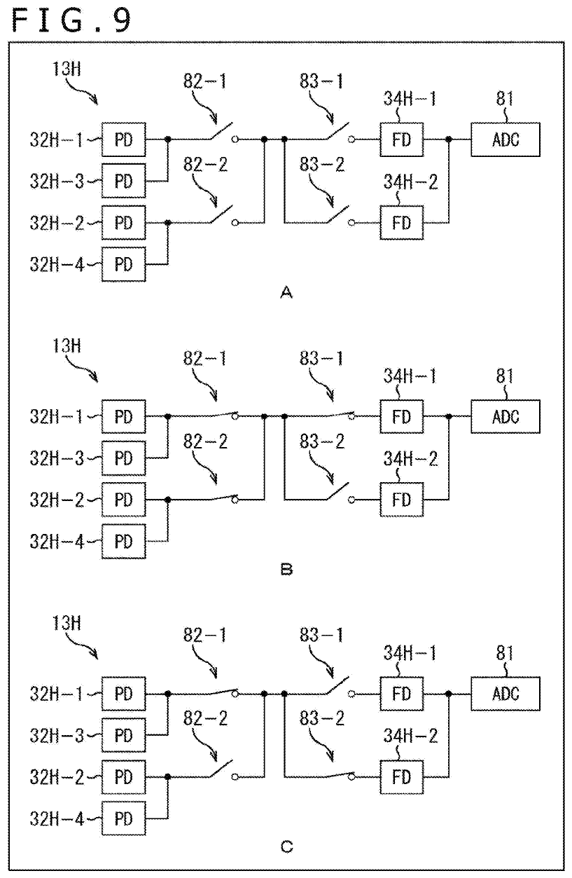

A configuration of a phase difference pixel 13H that can be switched over between an ordinary pixel mode and a phase difference pixel mode will be described with reference to FIG. 9.

The phase difference pixel 13H is configured with, for example, four PDs 32H-1 to 32H-4 as 4×4 PDs in length and width similarly to the phase difference pixel 13G of FIG. 6B. Although not depicted, the phase difference pixel 13H is also configured with the opening portions 38G-1 to 38G-4 and the large-sized microlens 61G described with reference to FIG. 6B.

Adding up all electric charges generated in the four PDs 32H-1 to 32H-4 enables the phase difference pixel 13H configured as described above to obtain output similar to, for example, output by the four-pixel addition for the ordinary pixels 12-1 to 12-4 described with reference to FIG. 8A. In other words, the phase difference pixel 13H can be switched over between the output of pixel signals used to construct an image similarly to the four-pixel addition for the ordinary pixels 12-1 to 12-4 and the output of pixel signals used for phase difference detection similarly to the phase difference pixel 13G. It is noted herein that a mode in which the phase difference pixel 13H outputs the pixel signals used to construct the image will be referred to as “ordinary pixel mode” and that the phase difference pixel 13H outputs the pixel signals used for the phase difference detection will be referred to as “phase difference pixel mode.”

Furthermore, as described above, in the image pickup element 11, the conversion efficiency of the phase difference pixel 13 at the time of converting the electric charge generated by the photoelectric conversion into the pixel signal is set to be twice as high as that of the ordinary pixel 12. It is, therefore, necessary to set the conversion efficiency of the phase difference pixel 13G in the phase difference pixel mode to be twice as high as that in the ordinary pixel mode.

As depicted in FIGS. 9, therefore, the phase difference pixel 13H is configured with switching transistors 83-1 and 83-2 so that two FD sections 34H-1 and 34H-2 can be switchably used. For example, the FD section 34H-1 is designed to have the same capacity as those of the ordinary pixels 12-1 to 12-4 subjected to the four-pixel addition, and the FD section 34H-2 is designed to have a capacity half as large as that of the FD section 34H-1 to obtain the conversion efficiency twice as high as that of the ordinary pixels 12-1 to 12-4. Furthermore, the switching transistor 83-1 is placed to connect the PD 32H-1 to 32H-4 to the FD section 34H-1, and the switching transistor 83-2 is placed to connect the PD 32H-1 to 32H-4 to the FD section 34H-2. For example, a signal processing circuit, not depicted, controls the switching transistors 83-1 and 83-2 to be turned on or off, thereby switching over between the ordinary pixel mode and the phase difference pixel mode.

As depicted in FIG. 9B, for example, when the phase difference pixel 13 is in the ordinary pixel mode, then the switching transistor 83-1 is turned on and the switching transistor 83-2 is turned off, and the electric charges generated in the PDs 32-1 to 32H-4 are transferred to the FD section 34H-1. The electric charges generated in the PDs 32H-1 to 32H-4 are converted into pixel signals with conversion efficiency similar to that of the ordinary pixels 12 in accordance with the capacity of the FD section 34H-1.

On the other hand, as depicted in FIG. 9C, when the phase difference pixel 13H is in the phase difference pixel mode, then the switching transistor 83-1 is turned off and the switching transistor 83-2 is turned on, and the electric charges generated in the PD32H-1 to 32H-4 are transferred to the FD section 34H-2. At this time, as described with reference to FIG. 8B, the electric charges generated in the PDs 32H-1 and 32H-3 are supplied to the FD section 34H-2 at the different timing from the timing of supplying thereto the electric charges generated in the PDs 32H-2 and 32H-4 by the switching transistors 82-1 and 82-2. The electric charges generated in the PDs 32H-1 and 32H-3 and the electric charges generated in the PDs 32H-2 and 32H-4 are thereby converted into pixel signals with the conversion efficiency twice as high as that in the ordinary pixel mode.

In this way, the phase difference pixel 13H can be switched over between the ordinary pixel mode and the phase difference pixel mode. In the phase difference pixel mode, the electric charges can be converted into the voltage representing pixel signals with the conversion efficiency twice as high as that in the ordinary pixel mode. It is noted that the phase difference pixel 13H may be configured with at least two PDs 32H, and a configuration of, for example, dividing the light-receiving area into halves by the two PDs 32H can be adopted as the configuration of the phase difference pixel 13H. Even with such a configuration, the electric charges generated in all the PDs 32H are converted into the voltage in the ordinary pixel mode, and the electric charge generated in one PD 32H (part of the PDs 32H) is converted into the voltage in the phase difference pixel mode.

### <Example of Configuration of Electronic Apparatus>

The image pickup element 11 described above can be applied to various kinds of electronic apparatuses such as an image pickup system, which is, for example, a digital still camera or a digital video camera, a cellular telephone having an image pickup function, and the other apparatus having an image pickup function.

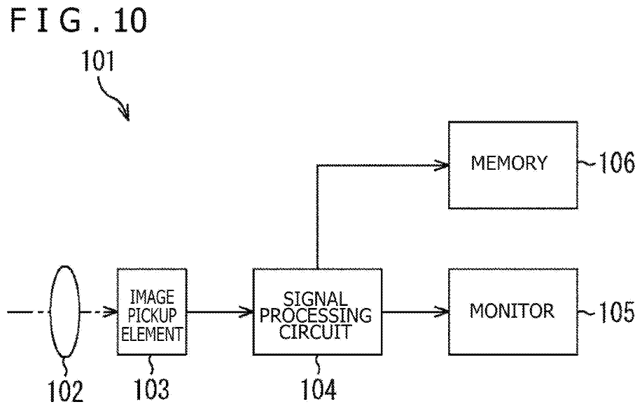

FIG. 10 is a block diagram depicting an example of a configuration of an image pickup apparatus mounted in an electronic apparatus.

As depicted in FIG. 10, an image pickup apparatus 101 is configured with an optical system 102, an image pickup element 103, a signal processing circuit 104, a monitor 105, and a memory 106.

The optical system 102 is configured with one or a plurality of lenses, guides image light (incident light) from a subject to the image pickup element 103, and forms an image on a light-receiving surface (sensor section) of the image pickup element 103.

The image pickup element 11 described above is applied to the image pickup element 103. Electrons are accumulated in the image pickup element 103 via the optical system 102 for a fixed period of time in response to the image formed on the light-receiving surface. Signals in response to the electrons accumulated in the image pickup element 103 are then supplied to the signal processing circuit 104.

The signal processing circuit 104 performs various signal processes on the pixel signals output from the image pickup element 103. An image (image data) obtained by performing the signal processes by the signal processing circuit 104 is supplied to and displayed on the monitor 105 or supplied to and stored (recorded) in the memory 106.

The image pickup apparatus 101 configured as described above can more accurately pick up, for example, an image in sharp focus by applying the image pickup element 11 described above.

<Usage Examples of using Image Sensor>

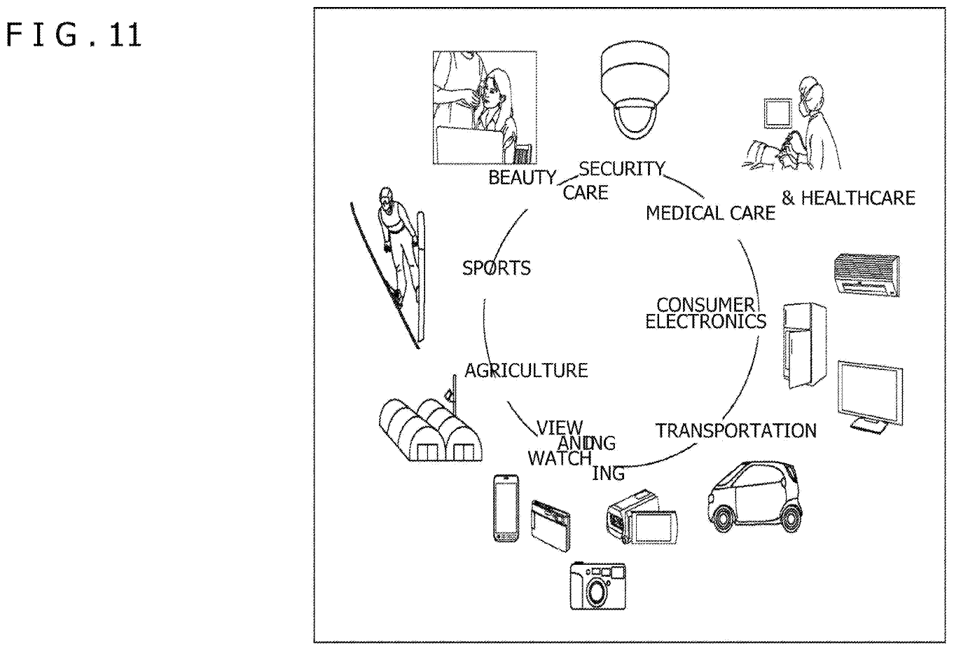

FIG. 11 is a diagram depicting usage examples of using the image sensor (image pickup element) described above.

The image sensor described above can be used in various cases of, for example, sensing light such as visible light, infrared light, ultraviolet light, and an X-ray as follows.
An apparatus such as a digital camera or a mobile apparatus having a camera function for capturing an image for use in viewing or watching.
An apparatus for use in traffic applications such as a vehicle-mounted sensor that captures images of a front, a rear, surroundings, an interior, and the like of a vehicle, a monitoring camera that monitors traveling vehicles and roads, and a range-finding sensor that measures a distance between vehicles and the like for safety driving such as automatic stop, recognition of a driver state, and the like.
An apparatus for use in home electric appliances such as a TV set, a refrigerator, and an air conditioner for capturing an image of a user gesture and operating such an appliance in accordance with the gesture.
An apparatus such as an endoscope and an apparatus performing angiography by receiving infrared light for use in medical care and healthcare applications.
An apparatus such as a monitoring camera for crime prevention and a camera for human recognition for use in security applications.
An apparatus such as a skin measuring instrument that captures an image of a skin and a microscope that captures an image of a scalp for use in beauty applications.
An apparatus such as an action camera and a wearable camera for sports for use in sport applications.
An apparatus such as a camera that monitors conditions of fields and crops for use in agricultural applications.

### APPLICATION EXAMPLE

The technology according to the present disclosure can be applied to various products. For example, the technology according to the present disclosure may be applied to a surgery room system.

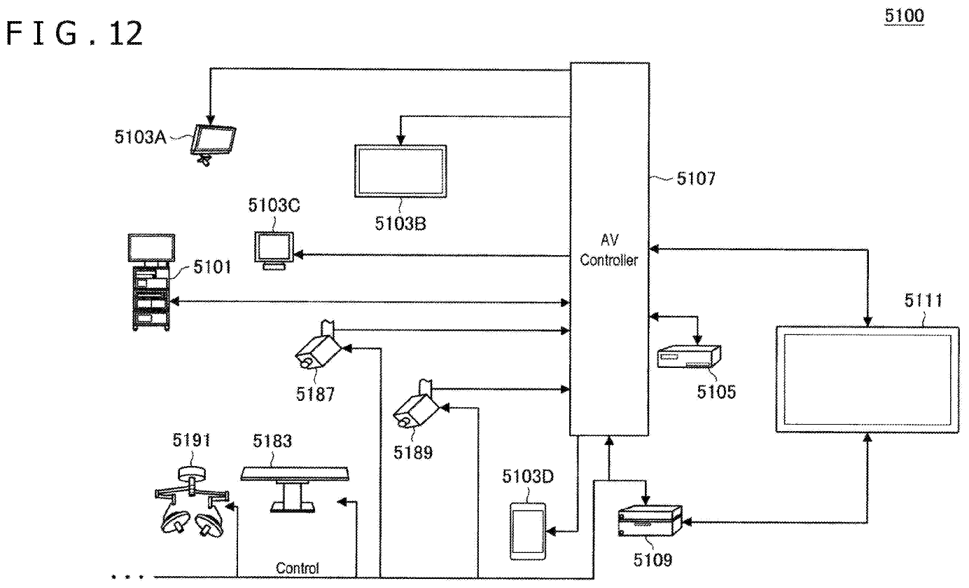

FIG. 12 is a view schematically depicting a general configuration of a surgery room system 5100 to which the technology according to an embodiment of the present disclosure can be applied. Referring to FIG. 12, the surgery room system 5100 is configured such that a group of apparatus installed in a surgery room are connected for cooperation with each other through an audiovisual (AV) controller 5107 and a surgery room controlling apparatus 5109.

In the surgery room, various apparatus may be installed. In FIG. 12, as an example, various apparatus group 5101 for endoscopic surgery, a ceiling camera 5187, a surgery field camera 5189, a plurality of display apparatus 5103A to 5103D, a recorder 5105, a patient bed 5183 and an illumination 5191 are depicted. The ceiling camera 5187 is provided on the ceiling of a surgery room and images the hands of a surgeon. The surgery field camera 5189 is provided on the ceiling of the surgery room and images a state of the entire surgery room.

Among the apparatus mentioned, the apparatus group 5101 belongs to an endoscopic surgery system 5113 hereinafter described and include an endoscope, a display apparatus which displays an image picked up by the endoscope and so forth. Various apparatus belonging to the endoscopic surgery system 5113 are referred to also as medical equipment. Meanwhile, the display apparatus 5103A to 5103D, the recorder 5105, the patient bed 5183 and the illumination 5191 are apparatus which are equipped, for example, in the surgery room separately from the endoscopic surgery system 5113. The apparatus which do not belong to the endoscopic surgery system 5113 are referred to also as non-medical equipment. The audiovisual controller 5107 and/or the surgery room controlling apparatus 5109 cooperatively control operation of the medical equipment and the non-medical equipment with each other.

The audiovisual controller 5107 integrally controls processes of the medical equipment and the non-medical equipment relating to image display. Specifically, each of the apparatus group 5101, the ceiling camera 5187 and the surgery field camera 5189 from among the apparatus provided in the surgery room system 5100 may be an apparatus having a function of sending information to be displayed during surgery (such information is hereinafter referred to as display information, and the apparatus mentioned is hereinafter referred to as apparatus of a sending source). Meanwhile, each of the display apparatus 5103A to 5103D may be an apparatus to which display information is outputted (the apparatus is hereinafter referred to also as apparatus of an output destination). Further, the recorder 5105 may be an apparatus which serves as both of an apparatus of a sending source and an apparatus of an output destination. The audiovisual controller 5107 has a function of controlling operation of an apparatus of a sending source and an apparatus of an output destination to acquire display information from the apparatus of a sending source and transmit the display information to the apparatus of an output destination so as to be displayed or recorded. It is to be noted that the display information includes various images picked up during surgery, various kinds of information relating to the surgery (for example, physical information of a patient, inspection results in the past or information regarding a surgical procedure) and so forth.

Specifically, to the audiovisual controller 5107, information relating to an image of a surgical region in a body lumen of a patient imaged by the endoscope may be transmitted as the display information from the apparatus group 5101. Further, from the ceiling camera 5187, information relating to an image of the hands of the surgeon picked up by the ceiling camera 5187 may be transmitted as display information. Further, from the surgery field camera 5189, information relating to an image picked up by the surgery field camera 5189 and illustrating a state of the entire surgery room may be transmitted as display information. It is to be noted that, if a different apparatus having an image pickup function exists in the surgery room system 5100, then the audiovisual controller 5107 may acquire information relating to an image picked up by the different apparatus as display information also from the different apparatus.

Alternatively, for example, in the recorder 5105, information relating to such images as mentioned above picked up in the past is recorded by the audiovisual controller 5107. The audiovisual controller 5107 can acquire, as display information, information relating to the images picked up in the past from the recorder 5105. It is to be noted that also various pieces of information relating to surgery may be recorded in advance in the recorder 5105.

The audiovisual controller 5107 controls at least one of the display apparatus 5103A to 5103D, which are apparatus of an output destination, to display acquired display information (namely, images picked up during surgery or various pieces of information relating to the surgery). In the example depicted, the display apparatus 5103A is a display apparatus installed so as to be suspended from the ceiling of the surgery room; the display apparatus 5103B is a display apparatus installed on a wall face of the surgery room; the display apparatus 5103C is a display apparatus installed on a desk in the surgery room; and the display apparatus 5103D is a mobile apparatus (for example, a tablet personal computer (PC)) having a display function.

Further, though not depicted in FIG. 12, the surgery room system 5100 may include an apparatus outside the surgery room. The apparatus outside the surgery room may be, for example, a server connected to a network constructed inside and outside the hospital, a PC used by medical staff, a projector installed in a meeting room of the hospital or the like. Where such an external apparatus is located outside the hospital, also it is possible for the audiovisual controller 5107 to cause display information to be displayed on a display apparatus of a different hospital through a teleconferencing system or the like to perform telemedicine.

The surgery room controlling apparatus 5109 integrally controls processes other than processes relating to image display on the non-medical equipment. For example, the surgery room controlling apparatus 5109 controls driving of the patient bed 5183, the ceiling camera 5187, the surgery field camera 5189 and the illumination 5191.

In the surgery room system 5100, a centralized operation panel 5111 is provided such that it is possible to issue an instruction regarding image display to the audiovisual controller 5107 or issue an instruction regarding operation of the non-medical equipment to the surgery room controlling apparatus 5109 through the centralized operation panel 5111. The centralized operation panel 5111 is configured by providing a touch panel on a display face of a display apparatus.

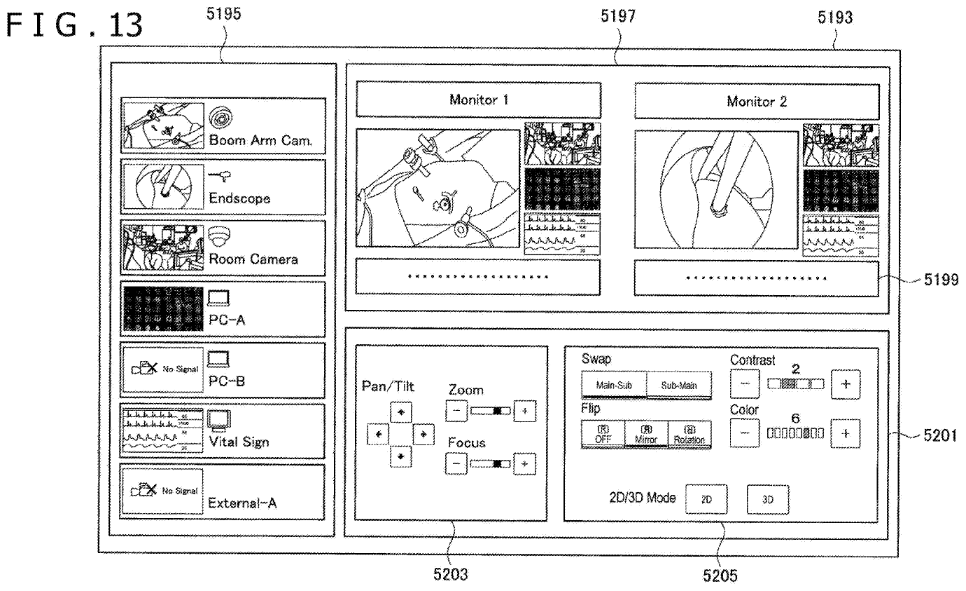

FIG. 13 is a view depicting an example of display of an operation screen image on the centralized operation panel 5111. In FIG. 13, as an example, an operation screen image is depicted which corresponds to a case in which two display apparatus are provided as apparatus of an output destination in the surgery room system 5100. Referring to FIG. 13, the operation screen image 5193 includes a sending source selection region 5195, a preview region 5197 and a control region 5201.

In the sending source selection region 5195, the sending source apparatus provided in the surgery room system 5100 and thumbnail screen images representative of display information the sending source apparatus have are displayed in an associated manner with each other. A user can select display information to be displayed on the display apparatus from any of the sending source apparatus displayed in the sending source selection region 5195.

In the preview region 5197, a preview of screen images displayed on two display apparatus (Monitor 1 and Monitor 2) which are apparatus of an output destination is displayed. In the example depicted, four images are displayed by picture in picture (PinP) display in regard to one display apparatus. The four images correspond to display information sent from the sending source apparatus selected in the sending source selection region 5195. One of the four images is displayed in a comparatively large size as a main image while the remaining three images are displayed in a comparatively small size as sub images. The user can exchange between the main image and the sub images by suitably selecting one of the images from among the four images displayed in the region. Further, a status displaying region 5199 is provided below the region in which the four images are displayed, and a status relating to surgery (for example, elapsed time of the surgery, physical information of the patient and so forth) may be displayed suitably in the status displaying region 5199.

A sending source operation region 5203 and an output destination operation region 5205 are provided in the control region 5201. In the sending source operation region 5203, a graphical user interface (GUI) part for performing an operation for an apparatus of a sending source is displayed. In the output destination operation region 5205, a GUI part for performing an operation for an apparatus of an output destination is displayed. In the example depicted, GUI parts for performing various operations for a camera (panning, tilting and zooming) in an apparatus of a sending source having an image pickup function are provided in the sending source operation region 5203. The user can control operation of the camera of an apparatus of a sending source by suitably selecting any of the GUI parts. It is to be noted that, though not depicted, where the apparatus of a sending source selected in the sending source selection region 5195 is a recorder (namely, where an image recorded in the recorder in the past is displayed in the preview region 5197), GUI parts for performing such operations as reproduction of the image, stopping of reproduction, rewinding, fast-feeding and so forth may be provided in the sending source operation region 5203.

Further, in the output destination operation region 5205, GUI parts for performing various operations for display on a display apparatus which is an apparatus of an output destination (swap, flip, color adjustment, contrast adjustment and switching between two dimensional (2D) display and three dimensional (3D) display) are provided. The user can operate the display of the display apparatus by suitably selecting any of the GUI parts.

It is to be noted that the operation screen image to be displayed on the centralized operation panel 5111 is not limited to the depicted example, and the user may be able to perform operation inputting to each apparatus which can be controlled by the audiovisual controller 5107 and the surgery room controlling apparatus 5109 provided in the surgery room system 5100 through the centralized operation panel 5111.

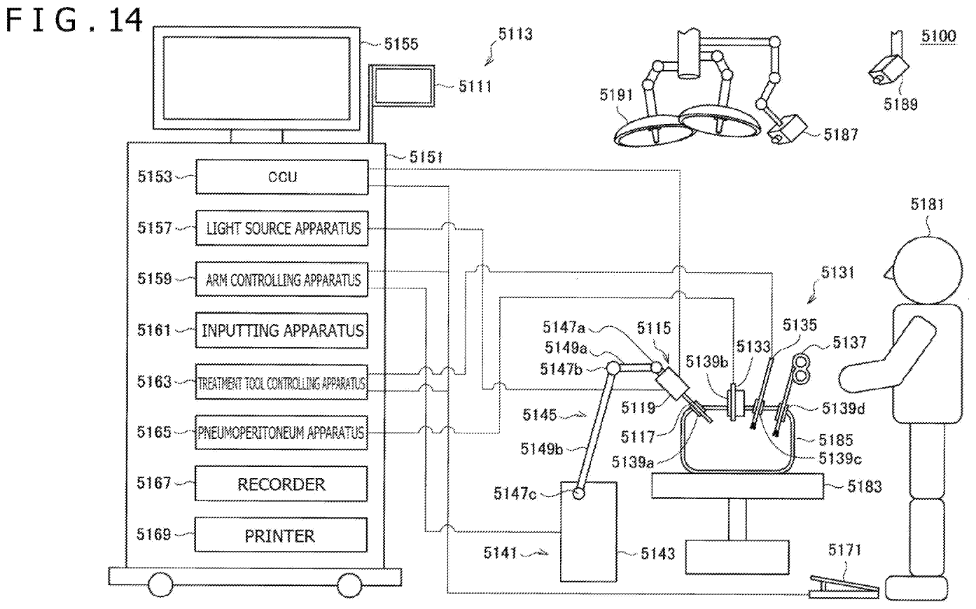

FIG. 14 is a view illustrating an example of a state of surgery to which the surgery room system described above is applied. The ceiling camera 5187 and the surgery field camera 5189 are provided on the ceiling of the surgery room such that it can image the hands of a surgeon (medical doctor) 5181 who performs treatment for an affected area of a patient 5185 on the patient bed 5183 and the entire surgery room. The ceiling camera 5187 and the surgery field camera 5189 may include a magnification adjustment function, a focal distance adjustment function, an imaging direction adjustment function and so forth. The illumination 5191 is provided on the ceiling of the surgery room and irradiates at least upon the hands of the surgeon 5181. The illumination 5191 may be configured such that the irradiation light amount, the wavelength (color) of the irradiation light, the irradiation direction of the light and so forth can be adjusted suitably.

The endoscopic surgery system 5113, the patient bed 5183, the ceiling camera 5187, the surgery field camera 5189 and the illumination 5191 are connected for cooperation with each other through the audiovisual controller 5107 and the surgery room controlling apparatus 5109 (not depicted in FIG. 14) as depicted in FIG. 12. The centralized operation panel 5111 is provided in the surgery room, and the user can suitably operate the apparatus existing in the surgery room through the centralized operation panel 5111 as described hereinabove.

In the following, a configuration of the endoscopic surgery system 5113 is described in detail. As depicted, the endoscopic surgery system 5113 includes an endoscope 5115, other surgical tools 5131, a supporting arm apparatus 5141 which supports the endoscope 5115 thereon, and a cart 5151 on which various apparatus for endoscopic surgery are mounted.

In endoscopic surgery, in place of incision of the abdominal wall to perform laparotomy, a plurality of tubular aperture devices called trocars 5139a to 5139d are used to puncture the abdominal wall. Then, a lens barrel 5117 of the endoscope 5115 and the other surgical tools 5131 are inserted into body lumens of the patient 5185 through the trocars 5139a to 5139d. In the example depicted, as the other surgical tools 5131, a pneumoperitoneum tube 5133, an energy treatment tool 5135 and forceps 5137 are inserted into body lumens of the patient 5185. Further, the energy treatment tool 5135 is a treatment tool for performing incision and peeling of a tissue, sealing of a blood vessel or the like by high frequency current or ultrasonic vibration. However, the surgical tools 5131 depicted are mere examples at all, and as the surgical tools 5131, various surgical tools which are generally used in endoscopic surgery such as, for example, a pair of tweezers or a retractor may be used.

An image of a surgical region in a body lumen of the patient 5185 picked up by the endoscope 5115 is displayed on a display apparatus 5155. The surgeon 5181 would use the energy treatment tool 5135 or the forceps 5137 while watching the image of the surgical region displayed on the display apparatus 5155 on the real time basis to perform such treatment as, for example, resection of an affected area. It is to be noted that, though not depicted, the pneumoperitoneum tube 5133, the energy treatment tool 5135, and the forceps 5137 are supported by the surgeon 5181, an assistant or the like during surgery.

### (Supporting Arm Apparatus)

The supporting arm apparatus 5141 includes an arm unit 5145 extending from a base unit 5143. In the example depicted, the arm unit 5145 includes joint portions 5147a, 5147b and 5147c and links 5149a and 5149b and is driven under the control of an arm controlling apparatus 5159. The endoscope 5115 is supported by the arm unit 5145 such that the position and the posture of the endoscope 5115 are controlled. Consequently, stable fixation in position of the endoscope 5115 can be implemented.

### (Endoscope)

The endoscope 5115 includes the lens barrel 5117 which has a region of a predetermined length from a distal end thereof to be inserted into a body lumen of the patient 5185, and a camera head 5119 connected to a proximal end of the lens barrel 5117. In the example depicted, the endoscope 5115 is depicted which is configured as a hard mirror having the lens barrel 5117 of the hard type. However, the endoscope 5115 may otherwise be configured as a soft mirror having the lens barrel 5117 of the soft type.

The lens barrel 5117 has, at a distal end thereof, an opening in which an objective lens is fitted. A light source apparatus 5157 is connected to the endoscope 5115 such that light generated by the light source apparatus 5157 is introduced to a distal end of the lens barrel 5117 by a light guide extending in the inside of the lens barrel 5117 and is applied toward an observation target in a body lumen of the patient 5185 through the objective lens. It is to be noted that the endoscope 5115 may be a direct view mirror or may be a perspective view mirror or a side view mirror.

An optical system and an image pickup element are provided in the inside of the camera head 5119 such that reflected light (observation light) from an observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 5153. It is to be noted that the camera head 5119 has a function incorporated therein for suitably driving the optical system of the camera head 5119 to adjust the magnification and the focal distance.

It is to be noted that, in order to establish compatibility with, for example, a stereoscopic vision (3D display), a plurality of image pickup elements may be provided on the camera head 5119. In this case, a plurality of relay optical systems are provided in the inside of the lens barrel 5117 in order to guide observation light to the plurality of respective image pickup elements.

### (Various Apparatus Incorporated in Cart)

The CCU 5153 includes a central processing unit (CPU), a graphics processing unit (GPU) or the like and integrally controls operation of the endoscope 5115 and the display apparatus 5155. Specifically, the CCU 5153 performs, for an image signal received from the camera head 5119, various image processes for displaying an image based on the image signal such as, for example, a development process (demosaic process). The CCU 5153 provides the image signal for which the image processes have been performed to the display apparatus 5155. Further, the audiovisual controller 5107 depicted in FIG. 12 is connected to the CCU 5153. The CCU 5153 provides the image signal for which the image processes have been performed also to the audiovisual controller 5107. Further, the CCU 5153 transmits a control signal to the camera head 5119 to control driving of the camera head 5119. The control signal may include information relating to an image pickup condition such as a magnification or a focal distance. The information relating to an image pickup condition may be inputted through the inputting apparatus 5161 or may be inputted through the centralized operation panel 5111 described hereinabove.

The display apparatus 5155 displays an image based on an image signal for which the image processes have been performed by the CCU 5153 under the control of the CCU 5153. If the endoscope 5115 is ready for imaging of a high resolution such as 4K (horizontal pixel number 3840×vertical pixel number 2160), 8K (horizontal pixel number 7680×vertical pixel number 4320) or the like and/or ready for 3D display, then a display apparatus by which corresponding display of the high resolution and/or 3D display are possible may be used as the display apparatus 5155. Where the apparatus is ready for imaging of a high resolution such as 4K or 8K, if the display apparatus used as the display apparatus 5155 has a size of equal to or not less than 55 inches, then a more immersive experience can be obtained. Further, a plurality of display apparatus 5155 having different resolutions and/or different sizes may be provided in accordance with purposes.

The light source apparatus 5157 includes a light source such as, for example, a light emitting diode (LED) and supplies irradiation light for imaging of a surgical region to the endoscope 5115.

The arm controlling apparatus 5159 includes a processor such as, for example, a CPU and operates in accordance with a predetermined program to control driving of the arm unit 5145 of the supporting arm apparatus 5141 in accordance with a predetermined controlling method.

An inputting apparatus 5161 is an input interface for the endoscopic surgery system 5113. A user can perform inputting of various kinds of information or instruction inputting to the endoscopic surgery system 5113 through the inputting apparatus 5161. For example, the user would input various kinds of information relating to surgery such as physical information of a patient, information regarding a surgical procedure of the surgery and so forth through the inputting apparatus 5161. Further, the user would input, for example, an instruction to drive the arm unit 5145, an instruction to change an image pickup condition (type of irradiation light, magnification, focal distance or the like) by the endoscope 5115, an instruction to drive the energy treatment tool 5135 or a like through the inputting apparatus 5161.

The type of the inputting apparatus 5161 is not limited and may be that of any one of various known inputting apparatus. As the inputting apparatus 5161, for example, a mouse, a keyboard, a touch panel, a switch, a foot switch 5171 and/or a lever or the like may be applied. Where a touch panel is used as the inputting apparatus 5161, it may be provided on the display face of the display apparatus 5155.

The inputting apparatus 5161 is otherwise a device to be mounted on a user such as, for example, a glasses type wearable device or a head mounted display (HMD), and various kinds of inputting are performed in response to a gesture or a line of sight of the user detected by any of the devices mentioned. Further, the inputting apparatus 5161 includes a camera which can detect a motion of a user, and various kinds of inputting are performed in response to a gesture or a line of sight of a user detected from a video picked up by the camera. Further, the inputting apparatus 5161 includes a microphone which can collect the voice of a user, and various kinds of inputting are performed by voice through the microphone. By configuring the inputting apparatus 5161 such that various kinds of information can be inputted in a contactless fashion in this manner, especially a user who belongs to a clean area (for example, the surgeon 5181) can operate an apparatus belonging to an unclean area in a contactless fashion. Further, since the user can operate an apparatus without releasing a possessed surgical tool from its hand, the convenience to the user is improved.

A treatment tool controlling apparatus 5163 controls driving of the energy treatment tool 5135 for cautery or incision of a tissue, sealing of a blood vessel or the like. A pneumoperitoneum apparatus 5165 feeds gas into a body lumen of the patient 5185 through the pneumoperitoneum tube 5133 to inflate the body lumen in order to secure the field of view of the endoscope 5115 and secure the working space for the surgeon. A recorder 5167 is an apparatus capable of recording various kinds of information relating to surgery. A printer 5169 is an apparatus capable of printing various kinds of information relating to surgery in various forms such as a text, an image or a graph.

In the following, especially a characteristic configuration of the endoscopic surgery system 5113 is described in more detail.

### (Supporting Arm Apparatus)

The supporting arm apparatus 5141 includes the base unit 5143 serving as a base, and the arm unit 5145 extending from the base unit 5143. In the example depicted, the arm unit 5145 includes the plurality of joint portions 5147a, 5147b and 5147c and the plurality of links 5149a and 5149b connected to each other by the joint portion 5147b. In FIG. 14, for simplified illustration, the configuration of the arm unit 5145 is depicted in a simplified form. Actually, the shape, number and arrangement of the joint portions 5147a to 5147c and the links 5149a and 5149b and the direction and so forth of axes of rotation of the joint portions 5147a to 5147c can be set suitably such that the arm unit 5145 has a desired degree of freedom. For example, the arm unit 5145 may preferably be included such that it has a degree of freedom equal to or not less than 6 degrees of freedom. This makes it possible to move the endoscope 5115 freely within the movable range of the arm unit 5145. Consequently, it becomes possible to insert the lens barrel 5117 of the endoscope 5115 from a desired direction into a body lumen of the patient 5185.

An actuator is provided in the joint portions 5147a to 5147c, and the joint portions 5147a to 5147c include such that they are rotatable around predetermined axes of rotation thereof by driving of the actuator. The driving of the actuator is controlled by the arm controlling apparatus 5159 to control the rotational angle of each of the joint portions 5147a to 5147c thereby to control driving of the arm unit 5145. Consequently, control of the position and the posture of the endoscope 5115 can be implemented. Thereupon, the arm controlling apparatus 5159 can control driving of the arm unit 5145 by various known controlling methods such as force control or position control.

For example, if the surgeon 5181 suitably performs operation inputting through the inputting apparatus 5161 (including the foot switch 5171), then driving of the arm unit 5145 may be controlled suitably by the arm controlling apparatus 5159 in response to the operation input to control the position and the posture of the endoscope 5115. After the endoscope 5115 at the distal end of the arm unit 5145 is moved from an arbitrary position to a different arbitrary position by the control just described, the endoscope 5115 can be supported fixedly at the position after the movement. It is to be noted that the arm unit 5145 may be operated in a master-slave fashion. In this case, the arm unit 5145 may be remotely controlled by the user through the inputting apparatus 5161 which is placed at a place remote from the surgery room.

Further, where force control is applied, the arm controlling apparatus 5159 may perform power-assisted control to drive the actuators of the joint portions 5147a to 5147c such that the arm unit 5145 may receive external force by the user and move smoothly following the external force. This makes it possible to move the arm unit 5145 with comparatively weak force when the user directly touches with and moves the arm unit 5145. Accordingly, it becomes possible for the user to move the endoscope 5115 more intuitively by a simpler and easier operation, and the convenience to the user can be improved.

Here, generally in endoscopic surgery, the endoscope 5115 is supported by a medical doctor called scopist. In contrast, where the supporting arm apparatus 5141 is used, the position of the endoscope 5115 can be fixed with a higher degree of certainty without hands, and therefore, an image of a surgical region can be obtained stably and surgery can be performed smoothly.

It is to be noted that the arm controlling apparatus 5159 may not necessarily be provided on the cart 5151. Further, the arm controlling apparatus 5159 may not necessarily be a single apparatus. For example, the arm controlling apparatus 5159 may be provided in each of the joint portions 5147a to 5147c of the arm unit 5145 of the supporting arm apparatus 5141 such that the plurality of arm controlling apparatus 5159 cooperate with each other to implement driving control of the arm unit 5145.

### (Light Source Apparatus)

The light source apparatus 5157 supplies irradiation light upon imaging of a surgical region to the endoscope 5115. The light source apparatus 5157 includes a white light source which includes, for example, an LED, a laser light source or a combination of them. In this case, where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 5157. Further, in this case, if laser beams from the RGB laser light sources are applied time-divisionally on an observation target and driving of the image pickup elements of the camera head 5119 is controlled in synchronism with the irradiation timings, then images individually corresponding to the R, G and B colors can be picked up time-divisionally. According to the method just described, a color image can be obtained even if a color filter is not provided for the image pickup element.

Further, driving of the light source apparatus 5157 may be controlled such that the intensity of light to be outputted is changed for each predetermined time. By controlling driving of the image pickup element of the camera head 5119 in synchronism with the timing of the change of the intensity of light to acquire images time-divisionally and synthesizing the images, an image of a high dynamic range free from underexposed blocked up shadows and overexposed highlights can be created.

Further, the light source apparatus 5157 may be configured to supply light of a predetermined wavelength band ready for special light observation. In special light observation, for example, by utilizing the wavelength dependency of absorption of light of a body tissue, narrow band light observation (narrow band imaging) of imaging a predetermined tissue such as a blood vessel of a superficial portion of the mucous membrane or the like in a high contrast is performed by applying light of a narrower band in comparison with irradiation light upon ordinary observation (namely, white light). Alternatively, in special light observation, fluorescent observation for obtaining an image from fluorescent light generated by irradiation of excitation light may also be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 5157 can be configured to supply such narrow-band light and/or excitation light suitable for special light observation as described above.

### (Camera Head and CCU)

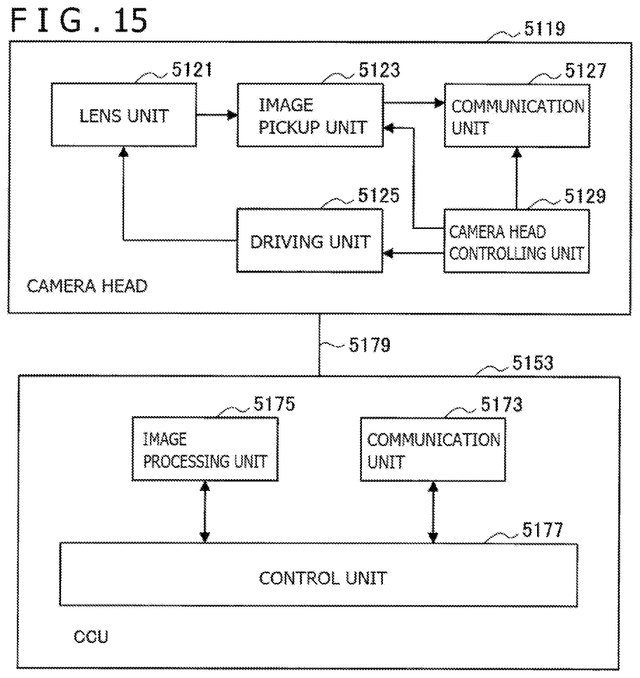

Functions of the camera head 5119 of the endoscope 5115 and the CCU 5153 are described in more detail with reference to FIG. 15. FIG. 15 is a block diagram depicting an example of a functional configuration of the camera head 5119 and the CCU 5153 depicted in FIG. 14.

Referring to FIG. 15, the camera head 5119 has, as functions thereof, a lens unit 5121, an image pickup unit 5123, a driving unit 5125, a communication unit 5127 and a camera head controlling unit 5129. Further, the CCU 5153 has, as functions thereof, a communication unit 5173, an image processing unit 5175 and a control unit 5177. The camera head 5119 and the CCU 5153 are connected to be bidirectionally communicable to each other by a transmission cable 5179.

First, a functional configuration of the camera head 5119 is described. The lens unit 5121 is an optical system provided at a connecting location of the camera head 5119 to the lens barrel 5117. Observation light taken in from a distal end of the lens barrel 5117 is introduced into the camera head 5119 and enters the lens unit 5121. The lens unit 5121 includes a combination of a plurality of lenses including a zoom lens and a focusing lens. The lens unit 5121 has optical properties adjusted such that the observation light is condensed on a light receiving face of the image pickup element of the image pickup unit 5123. Further, the zoom lens and the focusing lens include such that the positions thereof on their optical axis are movable for adjustment of the magnification and the focal point of a picked up image.

The image pickup unit 5123 includes an image pickup element and disposed at a succeeding stage to the lens unit 5121. Observation light having passed through the lens unit 5121 is condensed on the light receiving face of the image pickup element, and an image signal corresponding to the observation image is generated by photoelectric conversion. The image signal generated by the image pickup unit 5123 is provided to the communication unit 5127.

As the image pickup element which is included by the image pickup unit 5123, an image sensor, for example, of the complementary metal oxide semiconductor (CMOS) type is used which has a Bayer array and is capable of picking up an image in color. It is to be noted that, as the image pickup element, an image pickup element may be used which is ready, for example, for imaging of an image of a high resolution equal to or not less than 4K. If an image of a surgical region is obtained in a high resolution, then the surgeon 5181 can comprehend a state of the surgical region in enhanced details and can proceed with the surgery more smoothly.

Further, the image pickup element which is included by the image pickup unit 5123 is configured such that it has a pair of image pickup elements for acquiring image signals for the right eye and the left eye compatible with 3D display. Where 3D display is applied, the surgeon 5181 can comprehend the depth of a living body tissue in the surgical region with a higher degree of accuracy. It is to be noted that, if the image pickup unit 5123 is configured as that of the multi-plate type, then a plurality of systems of lens units 5121 are provided corresponding to the individual image pickup elements of the image pickup unit 5123.

The image pickup unit 5123 may not necessarily be provided on the camera head 5119. For example, the image pickup unit 5123 may be provided just behind the objective lens in the inside of the lens barrel 5117.

The driving unit 5125 includes an actuator and moves the zoom lens and the focusing lens of the lens unit 5121 by a predetermined distance along the optical axis under the control of the camera head controlling unit 5129. Consequently, the magnification and the focal point of a picked up image by the image pickup unit 5123 can be adjusted suitably.

The communication unit 5127 includes a communication apparatus for transmitting and receiving various kinds of information to and from the CCU 5153. The communication unit 5127 transmits an image signal acquired from the image pickup unit 5123 as RAW data to the CCU 5153 through the transmission cable 5179. Thereupon, in order to display a picked up image of a surgical region in low latency, preferably the image signal is transmitted by optical communication. This is because, since, upon surgery, the surgeon 5181 performs surgery while observing the state of an affected area through a picked up image, in order to achieve surgery with a higher degree of safety and certainty, it is demanded for a moving image of the surgical region to be displayed on the real time basis as far as possible. Where optical communication is applied, a photoelectric conversion module for converting an electric signal into an optical signal is provided in the communication unit 5127. After the image signal is converted into an optical signal by the photoelectric conversion module, it is transmitted to the CCU 5153 through the transmission cable 5179.

Further, the communication unit 5127 receives a control signal for controlling driving of the camera head 5119 from the CCU 5153. The control signal includes information relating to image pickup conditions such as, for example, information that a frame rate of a picked up image is designated, information that an exposure value upon image picking up is designated and/or information that a magnification and a focal point of a picked up image are designated. The communication unit 5127 provides the received control signal to the camera head controlling unit 5129. It is to be noted that also the control signal from the CCU 5153 may be transmitted by optical communication. In this case, a photoelectric conversion module for converting an optical signal into an electric signal is provided in the communication unit 5127. After the control signal is converted into an electric signal by the photoelectric conversion module, it is provided to the camera head controlling unit 5129.

It is to be noted that the image pickup conditions such as the frame rate, exposure value, magnification or focal point are set automatically by the control unit 5177 of the CCU 5153 on the basis of an acquired image signal. In other words, an auto exposure (AE) function, an auto focus (AF) function and an auto white balance (AWB) function are incorporated in the endoscope 5115.

The camera head controlling unit 5129 controls driving of the camera head 5119 on the basis of a control signal from the CCU 5153 received through the communication unit 5127. For example, the camera head controlling unit 5129 controls driving of the image pickup element of the image pickup unit 5123 on the basis of information that a frame rate of a picked up image is designated and/or information that an exposure value upon image picking up is designated. Further, for example, the camera head controlling unit 5129 controls the driving unit 5125 to suitably move the zoom lens and the focus lens of the lens unit 5121 on the basis of information that a magnification and a focal point of a picked up image are designated. The camera head controlling unit 5129 may include a function for storing information for identifying of the lens barrel 5117 and/or the camera head 5119.

It is to be noted that, by disposing the components such as the lens unit 5121 and the image pickup unit 5123 in a sealed structure having high airtightness and high waterproof, the camera head 5119 can be provided with resistance to an autoclave sterilization process.

Now, a functional configuration of the CCU 5153 is described. The communication unit 5173 includes a communication apparatus for transmitting and receiving various kinds of information to and from the camera head 5119. The communication unit 5173 receives an image signal transmitted thereto from the camera head 5119 through the transmission cable 5179. Thereupon, the image signal may be transmitted preferably by optical communication as described above. In this case, for the compatibility with optical communication, the communication unit 5173 includes a photoelectric conversion module for converting an optical signal into an electric signal. The communication unit 5173 provides the image signal after conversion into an electric signal to the image processing unit 5175.

Further, the communication unit 5173 transmits, to the camera head 5119, a control signal for controlling driving of the camera head 5119. Also the control signal may be transmitted by optical communication.

The image processing unit 5175 performs various image processes for an image signal in the form of RAW data transmitted thereto from the camera head 5119. The image processes include various known signal processes such as, for example, a development process, an image quality improving process (a bandwidth enhancement process, a super-resolution process, a noise reduction (NR) process and/or an image stabilization process) and/or an enlargement process (electronic zooming process). Further, the image processing unit 5175 performs a detection process for an image signal for performing AE, AF and AWB.

The image processing unit 5175 includes a processor such as a CPU or a GPU, and when the processor operates in accordance with a predetermined program, the image processes and the detection process described above can be performed. It is to be noted that, where the image processing unit 5175 includes a plurality of GPUs, the image processing unit 5175 suitably divides information relating to an image signal such that image processes are performed in parallel by the plurality of GPUs.

The control unit 5177 performs various kinds of control relating to image picking up of a surgical region by the endoscope 5115 and display of the picked up image. For example, the control unit 5177 generates a control signal for controlling driving of the camera head 5119. Thereupon, if image pickup conditions are inputted by the user, then the control unit 5177 generates a control signal on the basis of the input by the user. Alternatively, where the endoscope 5115 has an AE function, an AF function and an AWB function incorporated therein, the control unit 5177 suitably calculates an optimum exposure value, focal distance and white balance in response to a result of a detection process by the image processing unit 5175 and generates a control signal.

Further, the control unit 5177 controls the display apparatus 5155 to display an image of a surgical region on the basis of an image signal for which the image processes have been performed by the image processing unit 5175. Thereupon, the control unit 5177 recognizes various objects in the surgical region image using various image recognition technologies. For example, the control unit 5177 can recognize a surgical tool such as forceps, a particular living body region, bleeding, mist when the energy treatment tool 5135 is used and so forth by detecting the shape, color and so forth of edges of the objects included in the surgical region image. The control unit 5177 causes, when it controls the display apparatus 5155 to display a surgical region image, various kinds of surgery supporting information to be displayed in an overlapping manner with an image of the surgical region using a result of the recognition. Where surgery supporting information is displayed in an overlapping manner and presented to the surgeon 5181, the surgeon 5181 can proceed with the surgery more safety and certainty.

The transmission cable 5179 which connects the camera head 5119 and the CCU 5153 to each other is an electric signal cable ready for communication of an electric signal, an optical fiber ready for optical communication or a composite cable thereof.

Here, while, in the example depicted in the figure, communication is performed by wired communication using the transmission cable 5179, the communication between the camera head 5119 and the CCU 5153 may be performed otherwise by wireless communication. Where the communication between the camera head 5119 and the CCU 5153 is performed by wireless communication, there is no necessity to lay the transmission cable 5179 in the surgery room. Therefore, such a situation that movement of medical staff in the surgery room is disturbed by the transmission cable 5179 can be eliminated.

An example of the surgery room system 5100 to which the technology according to an embodiment of the present disclosure can be applied has been described above. It is to be noted here that, although a case in which the medical system to which the surgery room system 5100 is applied is the endoscopic surgery system 5113 has been described as an example, the configuration of the surgery room system 5100 is not limited to that of the example described above. For example, the surgery room system 5100 may be applied to a soft endoscopic system for inspection or a microscopic surgery system in place of the endoscopic surgery system 5113.

The technology according to the present disclosure can be suitably applied to the image pickup elements provided in the ceiling camera 5187, the surgery field camera 5189, the camera head 5119, and the like among the configurations described above. Applying the technology according to the present disclosure to those image pickup elements enables an image with higher focus accuracy to be output to an external display apparatus; thus, it is possible to achieve an improvement in diagnostic accuracy in telemedicine.

### <Example of Combination of Configurations>

It is noted that the present technology can be configured as follows.

(1) An image pickup element including:

a first pixel that converts an electric charge generated by photoelectric conversion into a voltage with first conversion efficiency and that outputs a pixel signal used to construct an image; and

a second pixel that converts an electric charge generated by the photoelectric conversion into a voltage with second conversion efficiency higher than the first conversion efficiency and that outputs a pixel signal used for phase difference detection.

(2) The image pickup element according to (1), in which

the conversion efficiency is set in accordance with a ratio of a light-receiving area by which the first pixel receives light to a light-receiving area by which the second pixel receives light.

(3) The image pickup element according to (2), in which

the light is blocked on the second pixel by approximately a half of the light-receiving area by a phase difference light blocking film that exhibits a light blocking effect, and

the second conversion efficiency is approximately twice as high as the first conversion efficiency.

(4) The image pickup element according to any one of (1) to (3), in which

each of the first pixel and the second pixel includes:
a photoelectric conversion section that photoelectrically converts received light;
a floating diffusion region that temporarily accumulates the electric charge generated in the photoelectric conversion section; and
an electric charge/voltage conversion section that converts the electric charge accumulated in the floating diffusion region into a voltage representing the pixel signal with conversion efficiency according to a capacity of the floating diffusion region,

the capacity of the floating diffusion region of the second pixel is designed to be smaller than the capacity of the floating diffusion region of the first pixel.

(5) The image pickup element according to (4), in which

the second conversion efficiency is set to be approximately twice as high as the first conversion efficiency by designing the capacity of the floating diffusion region of the second pixel to be approximately half as large as the capacity of the floating diffusion region of the first pixel.

(6) The image pickup element according to any one of (1) to (5), in which

the second pixel is configured such that four photoelectric conversion sections are placed as 2×2 photoelectric conversion sections in length and width, and

the image pickup element further includes a microlens at a size according to a region where the four photoelectric conversion sections are placed.

(7) The image pickup element according to (6), in which

a color filter for receiving red, green, or blue light is placed per four first pixels placed as the 2×2 pixels in length and width.

(8) The image pickup element according to any one of (1) to (7), in which

the second pixel can be switched over between a first mode for outputting the pixel signal used to construct the image and a second mode for outputting the pixel signal used for the phase difference detection, converts the electric charge into the voltage with the first conversion efficiency in the first mode, and converts the electric charge into the voltage with the second conversion efficiency in the second mode.

(9) The image pickup element according to (8), in which

the second pixel is configured with two or more photoelectric conversion sections, converts electric charges generated in all of the photoelectric conversion sections into the voltage in a case of the first mode, and converts the electric charge generated in part of the photoelectric conversion section into the voltage in a case of the second mode.

(10) An image pickup apparatus including:

an image pickup element including
a first pixel that converts an electric charge generated by photoelectric conversion into a voltage with first conversion efficiency and that outputs a pixel signal used to construct an image and
a second pixel that converts an electric charge generated by the photoelectric conversion into a voltage with second conversion efficiency higher than the first conversion efficiency and that outputs an image signal used for phase difference detection.

(11) The image pickup element according to (10), in which

the conversion efficiency is set in accordance with a ratio of a light-receiving area by which the first pixel receives light to a light-receiving area by which the second pixel receives light.

(12) The image pickup element according to (11), in which

the light is blocked on the second pixel by approximately a half of the light-receiving area by a phase difference light blocking film that exhibits a light blocking effect, and

the second conversion efficiency is approximately twice as high as the first conversion efficiency.

(13) The image pickup element according to any one of (10) to (12), in which

each of the first pixel and the second pixel includes:
a photoelectric conversion section that photoelectrically converts received light;
a floating diffusion region that temporarily accumulates the electric charge generated in the photoelectric conversion section; and
an electric charge/voltage conversion section that converts the electric charge accumulated in the floating diffusion region into a voltage representing the pixel signal with conversion efficiency according to a capacity of the floating diffusion region,

the capacity of the floating diffusion region of the second pixel is designed to be smaller than the capacity of the floating diffusion region of the first pixel.

(14) The image pickup element according to (13), in which

the second conversion efficiency is set to be approximately twice as high as the first conversion efficiency by designing the capacity of the floating diffusion region of the second pixel to be approximately half as large as the capacity of the floating diffusion region of the first pixel.

(15) The image pickup element according to any one of (10) to (14), in which

the second pixel is configured such that four photoelectric conversion sections are placed as 2×2 photoelectric conversion sections in length and width, and

the image pickup element further includes a microlens at a size according to a region where the four photoelectric conversion sections are placed.

(16) The image pickup element according to (15), in which

a color filter for receiving red, green, or blue light is placed per four first pixels placed as the 2×2 pixels in length and width.

(17) The image pickup element according to any one of (10) to (16), in which

the second pixel can be switched over between a first mode for outputting the pixel signal used to construct the image and a second mode for outputting the pixel signal used for the phase difference detection, converts the electric charge into the voltage with the first conversion efficiency in the first mode, and converts the electric charge into the voltage with the second conversion efficiency in the second mode.

(18) The image pickup element according to (17), in which

the second pixel is configured with two or more photoelectric conversion sections, converts electric charges generated in all of the photoelectric conversion sections into the voltage in a case of the first mode, and converts the electric charge generated in part of the photoelectric conversion sections into the voltage in a case of the second mode.

The embodiments of the present disclosure are not limited to the embodiments described above and various changes and modifications can be made without departing from the spirit of the present disclosure. Furthermore, the advantages described in the present specification are given as an example only, and the advantages are not limited to those described in the present specification and may contain other advantages.

### REFERENCE SIGNS LIST

11 Imaging element, 12 Ordinary pixel, 13 Phase difference pixel, 21 Semiconductor substrate, 22 Planarization layer, 23 Filter layer, 24 On-chip lens layer, 31 Silicon wafer, 32 PD, 33 Transfer transistor, 34 FD section, 35 Inter-pixel light blocking film, 36 Phase difference light blocking film, 37, 38 Opening portion, 41 Oxide film, 51 Color filter, 52 Transparent filter, 61 Microlens, 71 Amplification transistor, 72 Selection transistor, 73 Vertical signal line, 81 AD converter, 82 Switching transistor

1. An image pickup element comprising:
a first pixel that converts an electric charge generated by photoelectric conversion into a voltage with first conversion efficiency and that outputs a pixel signal used to construct an image; and
a second pixel that converts an electric charge generated by the photoelectric conversion into a voltage with second conversion efficiency higher than the first conversion efficiency and that outputs a pixel signal used for phase difference detection.

2. The image pickup element according to claim 1, wherein
the conversion efficiency is set in accordance with a ratio of a light-receiving area by which the first pixel receives light to a light-receiving area by which the second pixel receives light.

3. The image pickup element according to claim 2, wherein
the light is blocked on the second pixel by approximately a half of the light-receiving area by a phase difference light blocking film that exhibits a light blocking effect, and
the second conversion efficiency is approximately twice as high as the first conversion efficiency.

4. The image pickup element according to claim 1, wherein
each of the first pixel and the second pixel includes:
a photoelectric conversion section that photoelectrically converts received light;
a floating diffusion region that temporarily accumulates the electric charge generated in the photoelectric conversion section; and
an electric charge/voltage conversion section that converts the electric charge accumulated in the floating diffusion region into a voltage representing the pixel signal with conversion efficiency according to a capacity of the floating diffusion region,
the capacity of the floating diffusion region of the second pixel is designed to be smaller than the capacity of the floating diffusion region of the first pixel.

5. The image pickup element according to claim 4, wherein
the second conversion efficiency is set to be approximately twice as high as the first conversion efficiency by designing the capacity of the floating diffusion region of the second pixel to be approximately half as large as the capacity of the floating diffusion region of the first pixel.

6. The image pickup element according to claim 1, wherein
the second pixel is configured such that four photoelectric conversion sections are placed as 2×2 photoelectric conversion sections in length and width, and
the image pickup element further includes a microlens at a size according to a region where the four photoelectric conversion sections are placed.

7. The image pickup element according to claim 6, wherein
a color filter for receiving red, green, or blue light is placed per four first pixels placed as the 2×2 pixels in length and width.

8. The image pickup element according to claim 1, wherein
the second pixel is switched over between a first mode for outputting the pixel signal used to construct the image and a second mode for outputting the pixel signal used for the phase difference detection, converts the electric charge into the voltage with the first conversion efficiency in the first mode, and converts the electric charge into the voltage with the second conversion efficiency in the second mode.

9. The image pickup element according to claim 8, wherein
the second pixel is configured with two or more photoelectric conversion sections, converts electric charges generated in all of the photoelectric conversion sections into the voltage in a case of the first mode, and converts the electric charge generated in part of the photoelectric conversion section into the voltage in a case of the second mode.

10. An image pickup apparatus comprising:
an image pickup element including
a first pixel that converts an electric charge generated by photoelectric conversion into a voltage with first conversion efficiency and that outputs a pixel signal used to construct an image, and
a second pixel that converts an electric charge generated by the photoelectric conversion into a voltage with second conversion efficiency higher than the first conversion efficiency and that outputs a pixel signal used for phase difference detection.

11. The image pickup apparatus according to claim 10, wherein
the conversion efficiency is set in accordance with a ratio of a light-receiving area by which the first pixel receives light to a light-receiving area by which the second pixel receives light.

12. The image pickup apparatus according to claim 11, wherein
the light is blocked on the second pixel by approximately a half of the light-receiving area by a phase difference light blocking film that exhibits a light blocking effect, and
the second conversion efficiency is approximately twice as high as the first conversion efficiency.

13. The image pickup apparatus according to claim 10, wherein
each of the first pixel and the second pixel includes:
a photoelectric conversion section that photoelectrically converts received light;
a floating diffusion region that temporarily accumulates the electric charge generated in the photoelectric conversion section; and
an electric charge/voltage conversion section that converts the electric charge accumulated in the floating diffusion region into a voltage representing the pixel signal with conversion efficiency according to a capacity of the floating diffusion region,
the capacity of the floating diffusion region of the second pixel is designed to be smaller than the capacity of the floating diffusion region of the first pixel.

14. The image pickup apparatus according to claim 13, wherein
the second conversion efficiency is set to be approximately twice as high as the first conversion efficiency by designing the capacity of the floating diffusion region of the second pixel to be approximately half as large as the capacity of the floating diffusion region of the first pixel.

15. The image pickup apparatus according to claim 10, wherein
the second pixel is configured such that four photoelectric conversion sections are placed as 2×2 photoelectric conversion sections in length and width, and
the image pickup apparatus further includes a microlens at a size according to a region where the four photoelectric conversion sections are placed.

16. The image pickup apparatus according to claim 15, wherein
a color filter for receiving red, green, or blue light is placed per four first pixels placed as the 2×2 pixels in length and width.

17. The image pickup apparatus according to claim 10, wherein
the second pixel is switched over between a first mode for outputting the pixel signal used to construct the image and a second mode for outputting the pixel signal used for the phase difference detection, converts the electric charge into the voltage with the first conversion efficiency in the first mode, and converts the electric charge into the voltage with the second conversion efficiency in the second mode.

18. The image pickup apparatus according to claim 17, wherein
the second pixel is configured with two or more photoelectric conversion sections, converts electric charges generated in all of the photoelectric conversion sections into the voltage in a case of the first mode, and converts the electric charge generated in part of the photoelectric conversion sections into the voltage in a case of the second mode.
